(19) United States
(12) Patent Application Publication
(10) Pub. No.: US 2016/0238872 A1
(43) Pub. Date: Aug. 18, 2016

(54) ARRAY SUBSTRATE AND LIQUID CRYSTAL DISPLAY PANEL USING SAME

(71) Applicant: SHENZHEN CHINA STAR OPTOELECTRONICS TECHNOLOGY CO., LTD., Guangdong (CN)

(72) Inventors: Chihyuan TSENG, Shenzhen, Guangdong (CN); Shuichih LIEN, Shenzhen, Guangdong (CN); Changcheng LO, Shenzhen, Guangdong (CN)

(73) Assignee: Shenzhen China Star Optoelectronics Technology Co., Ltd., Shenzhen, Guangdong (CN)

(21) Appl. No.: 14/379,285

(22) PCT Filed: Jan. 10, 2014
(86) PCT No.: PCT/CN2014/070425

§ 371 Date: Aug. 15, 2014

(30) Foreign Application Priority Data
Dec. 27, 2013 (CN) 201310739608.1

(51) Int. Cl. G02F 1/1345; G02F 1/1343; H01L 29/423; H01L 27/12; H01L 29/24; G02F 1/1368; H01L 29/786

(52) U.S. Cl. CPC G02F 1/13452; G02F 1/1368; G02F 1/134309; G02F 1/13439; H01L 29/7869; H01L 27/1225; H01L 27/1218; H01L 27/1248; H01L 29/24; H01L 29/42356; G02F 2001/136222

(57) ABSTRACT

The present invention provides an array substrate and a liquid crystal display panel using the array substrate. The array substrate includes: a glass substrate (20), a gate terminal (22) formed on the glass substrate (20), a gate insulation layer (23) formed on the gate terminal (22), an oxide semiconductor layer (24) formed on the gate insulation layer (23), source/drain terminals (25) formed on the oxide semiconductor layer (24) and the gate insulation layer (23), a protective layer (26) formed on the oxide semiconductor layer (24), the source/drain terminals (25), and the gate insulation layer (23), a color filter (27) formed on the protective layer (26), a planarization layer (28) formed on the color filter (27) and the protective layer (26), and a pixel electrode (29) formed on the planarization layer (28). The pixel electrode (29) is electrically connected to the source/drain terminals (25) and the pixel electrode (29) includes an arrangement of lines that forms a radiating structure surrounding a center defined by a cross-shaped structure.

### BACKGROUND OF THE INVENTION

1. Field of the Invention

The present invention relates to the field of flat panel displaying, and in particular to an array substrate and a liquid crystal display panel using the array substrate.

2. The Related Arts

Liquid crystal displays (LCDs) have a variety of advantages, such as thin device body, low power consumption, and being free of radiation, and are thus of wide applications, such as mobile phones, personal digital assistants (PDAs), digital cameras, computer monitors, and notebook computer screens.

Most of the liquid crystal displays that are currently available in the market are backlighting liquid crystal displays, which comprise an enclosure, a liquid crystal display panel arranged in the enclosure, and a backlight module mounted in the enclosure. The structure of a conventional liquid crystal display panel is composed of a color filter (CF) substrate, a thin-film transistor (TFT) array substrate, and a liquid crystal layer arranged between the two substrates and the principle of operation is that a driving voltage is applied to the two glass substrates to control rotation of the liquid crystal molecules of the liquid crystal layer in order to refract out light emitting from the backlight module for generating images. Since the liquid crystal display panel itself does not emit light, light must be provided from the backlight module in order to normally display images. Thus, the backlight module is one of the key components of the liquid crystal displays. The backlight modules can be classified in two types, namely a side-edge backlight module and a direct backlight module, according to the site where light gets incident. The direct backlight module comprises a light source, such as a cold cathode fluorescent lamp (CCFL) or a light-emitting diode (LED), which is arranged at the backside of the liquid crystal display panel to form a planar light source directly supplied to the liquid crystal display panel. The side-edge backlight module comprises an LED light bar, serving as a backlight source, which is arranged at an edge of a backplane to be located rearward of one side of the liquid crystal display panel. The LED light bar emits light that enters a light guide plate (LGP) through a light incident face at one side of the light guide plate and is projected out of a light emergence face of the light guide plate, after being reflected and diffused, to pass through an optic film assembly so as to form a planar light source for the liquid crystal display panel.

Referring to FIG. 1, a schematic view is given to show the structure of a conventional liquid crystal display panel, which comprises an array substrate 100, a color filter (CF) substrate 300 laminated to the array substrate 100, and a liquid crystal (LC) layer 500 arranged between the array substrate 100 and the color filter substrate 300, wherein the color filter substrate 300 comprises a pixel structure formed thereon to realize color displaying.

With the progress of technology, what is currently available in a liquid crystal display panel that combines a pixel structure with an array substrate and is referred to as COA (Color Filter On Array) technology. Based on such technology, a coplanar liquid crystal display panel (as shown in FIG. 2) is available, which comprises: an array substrate 100′, a color filter substrate 300′ laminated to the array substrate 100′, and a liquid crystal layer 500′ arranged between the array substrate 100′ and the color filter substrate 300′, wherein the array substrate 100′ comprises a thin-film transistor (TFT) array and a pixel structure formed thereon. The thin-film transistor array comprises: a gate terminal 102, a gate insulation layer 104 formed on the gate terminal 102, an oxide semiconductor 106 formed on the gate insulation layer 104, and source/drain terminals 108 formed on the gate insulation layer 104 and the oxide semiconductor layer 106. The oxide semiconductor layer 106 is generally formed of indium gallium zinc oxide (IGZO) and in the manufacturing process thereof, after formation of the oxide semiconductor layer 106, a second metal (M2) layer is formed on the oxide semiconductor layer 106 and the gate insulation layer 104 and then subjected to etching. However, forming of the second metal layer readily causes damages to the surface of the oxide semiconductor layer 106, making the surface of the oxide semiconductor layer 106 relatively roughened, thereby leading to worsened property of the thin-film transistor.

Further, in such a liquid crystal display panel, the pixel structure of a pixel electrode 109 (as shown in FIG. 3) is an entire solid surface structure. Such a structure leads to a relatively small aperture ratio of the liquid crystal display panel, thereby resulting in poor displaying performance of the liquid crystal display panel.

### SUMMARY OF THE INVENTION

An object of the present invention is to provide an array substrate, which has a simple structure and excellent electrical property.

Another object of the present invention is to provide a liquid crystal display panel, which has a simple structure, a large aperture ratio, and excellent displaying performance.

To achieve the above objects, the present invention provides an array substrate, which comprises: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer. The pixel electrode is electrically connected to the source/drain terminals. The pixel electrode comprises an arrangement of lines that forms a radiating structure surrounding a center defined by a cross-shaped structure.

The oxide semiconductor layer comprises a recess formed thereon to be located between the source/drain terminals and the protective layer is formed on the source/drain terminals, the gate insulation layer, and the recess.

The oxide semiconductor layer comprises an indium gallium zinc oxide layer.

The pixel electrode is formed of nano indium tin oxide.

The present invention also provides a liquid crystal display panel, which comprises: an array substrate, a color filter substrate laminated to the array substrate, and a liquid crystal layer arranged between the array substrate and the color filter substrate. The array substrate comprises: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer. The pixel electrode is electrically connected to the source/drain terminals. The pixel electrode comprises an arrangement of lines that forms a radiating structure surrounding a center defined by a cross-shaped structure.

The oxide semiconductor layer comprises a recess formed thereon to be located between the source/drain terminals and the protective layer is formed on the source/drain terminals, the gate insulation layer, and the recess.

The oxide semiconductor layer comprises an indium gallium zinc oxide layer and the pixel electrode is formed of nano indium tin oxide.

The liquid crystal display panel further comprises a black matrix and a spacer arranged between the array substrate and the color filter substrate.

The black matrix and the spacer are formed on the color filter substrate.

The black matrix and the spacer are formed on the array substrate.

The present invention further provides a liquid crystal display panel, which comprises: an array substrate, a color filter substrate laminated to the array substrate, and a liquid crystal layer arranged between the array substrate and the color filter substrate, the array substrate comprising: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer, the pixel electrode being electrically connected to the source/drain terminals, the pixel electrode comprising an arrangement of lines that forms a radiating structure surrounding a center defined by a cross-shaped structure;

wherein the oxide semiconductor layer comprises a recess formed thereon to be located between the source/drain terminals and the protective layer is formed on the source/drain terminals, the gate insulation layer, and the recess.

The oxide semiconductor layer comprises an indium gallium zinc oxide layer and the pixel electrode is formed of nano indium tin oxide.

The liquid crystal display panel further comprises a black matrix and a spacer arranged between the array substrate and the color filter substrate.

The black matrix and the spacer are formed on the color filter substrate.

The black matrix and the spacer are formed on the array substrate.

The efficacy of the present invention is that the present invention provides an array substrate and a liquid crystal display panel using the array substrate, in which a color filter is arranged on the array substrate and a pixel electrode is provided in an arrangement of lines that forms a radiating structure surrounding a center defined by a cross-shaped structure so as to effectively increase the aperture ratio and enhance the displaying performance. Further, a recess is formed in the oxide semiconductor layer between the source/drain terminals to remove the damaged portion of the surface of the oxide semiconductor layer resulting from the forming of the source/drain terminals so as to effectively improve electrical property and enhance the quality of the liquid crystal display panel.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a cross-sectional view showing the structure of a conventional liquid crystal display panel;

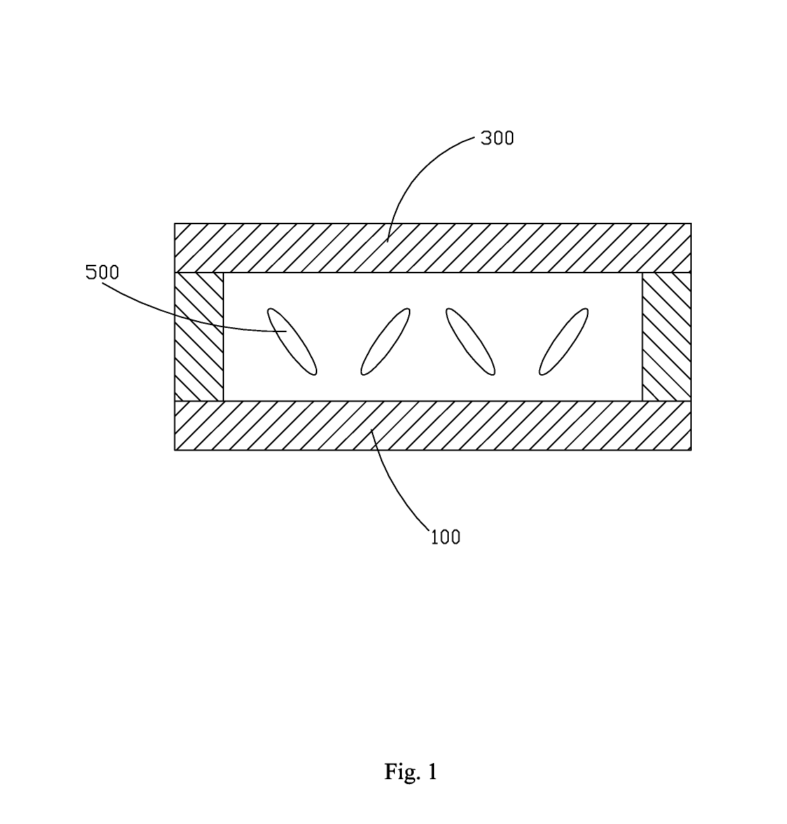

FIG. 2 is a schematic view showing a conventional liquid crystal display panel having a COA (Color Filter On Array) structure;

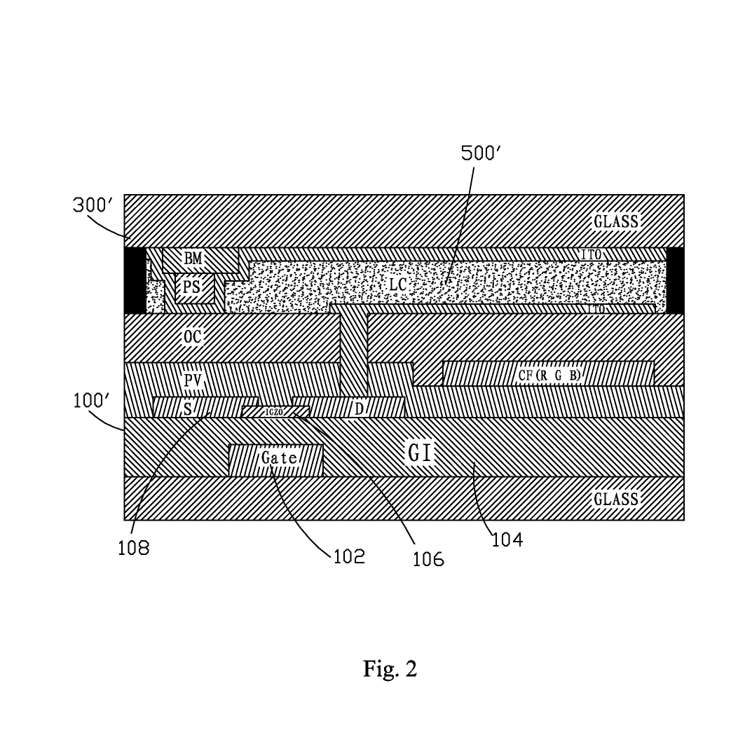

FIG. 3 is a schematic view showing a pixel structure of the liquid crystal display panel of FIG. 2;

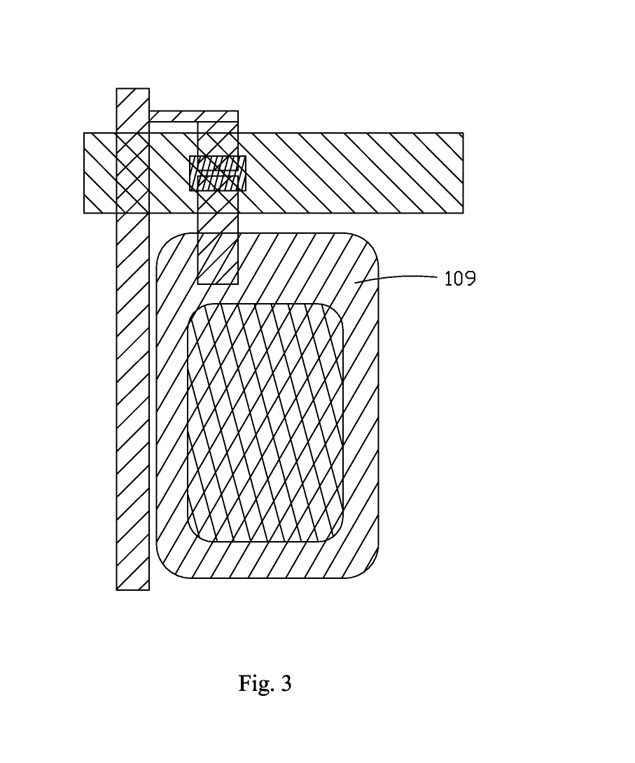

FIG. 4 is a schematic view showing the structure of an array substrate according to the present invention;

FIG. 5 is a schematic view showing a pixel structure of the array substrate according to the present invention; and

FIG. 6 is a schematic view showing the structure of a liquid crystal display panel according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

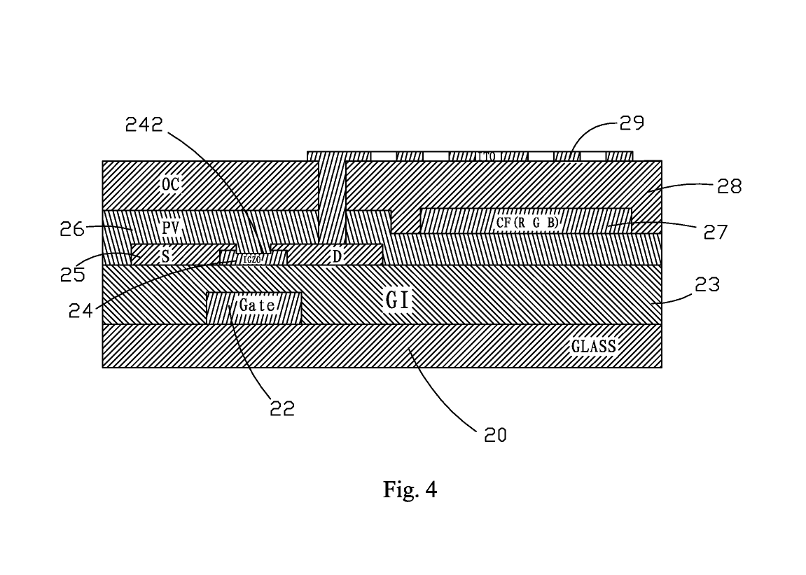

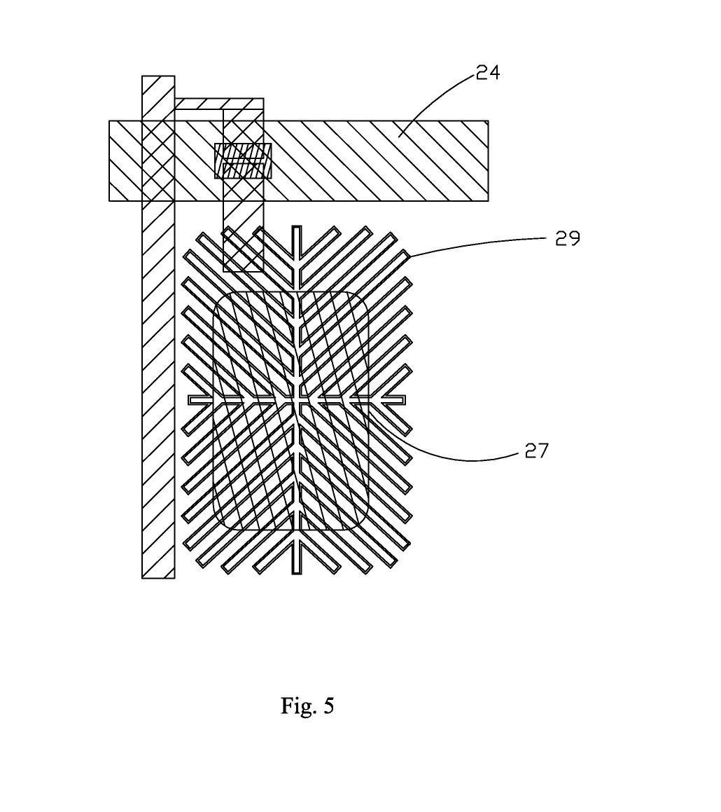

Referring to FIGS. 4 and 5, the present invention provides an array substrate, which comprises: a glass substrate 20, a gate terminal 22 formed on the glass substrate 20, a gate insulation layer 23 formed on the gate terminal 22 and the glass substrate 20, an oxide semiconductor layer 24 formed on the gate insulation layer 23, source/drain terminals 25 formed on the oxide semiconductor layer 24 and the gate insulation layer 23, a protective layer 26 formed on the oxide semiconductor layer 24, the source/drain terminals 25, and the gate insulation layer 23, a color filter 27 formed on the protective layer 26, a planarization layer 28 formed on the color filter 27 and the protective layer 26, and a pixel electrode 29 formed on the planarization layer 28. The pixel electrode 29 is electrically connected to the source/drain terminals 25 and the pixel electrode 29 comprises an arrangement of lines that forms a radiating structure surrounding a center defined by a cross-shaped structure so as to effectively increase the aperture ratio and enhance the displaying performance.

The gate terminal 22, the gate insulation layer 23, the oxide semiconductor layer 24, and the source/drain terminals 25 collectively constitute a thin-film transistor for realizing control of driving. The color filter 27 functions to realize color displaying.

Further, the oxide semiconductor layer 24 comprises a recess 242 formed thereon to be located between the source/drain terminals 25. The protective layer 26 is formed on the source/drain terminals 25, the gate insulation layer 23, and the recess 242. A specific manufacture operation is that after the oxide semiconductor layer 24 is formed on the gate insulation layer 23, a second metal (M2) layer is formed on the oxide semiconductor layer 24 and the gate insulation layer 23 and the second metal layer is subjected to etching to form the source/drain terminals 25. Under this condition, the portion of the oxide semiconductor layer 24 between the source/drain terminals 25 is exposed. The surface of the exposed portion is damaged due to being bombarded by the second metal layer and this leads to poor property of the thin-film transistor. By subjecting the exposed portion of the oxide semiconductor layer 24 to etching again to etch off the damaged portion, it can then ensure the property of the thin-film transistor.

In the instant embodiment, the oxide semiconductor layer 24 is an indium gallium zinc oxide (IGZO) layer. The pixel electrode 29 is formed of nano indium tin oxide (ITO).

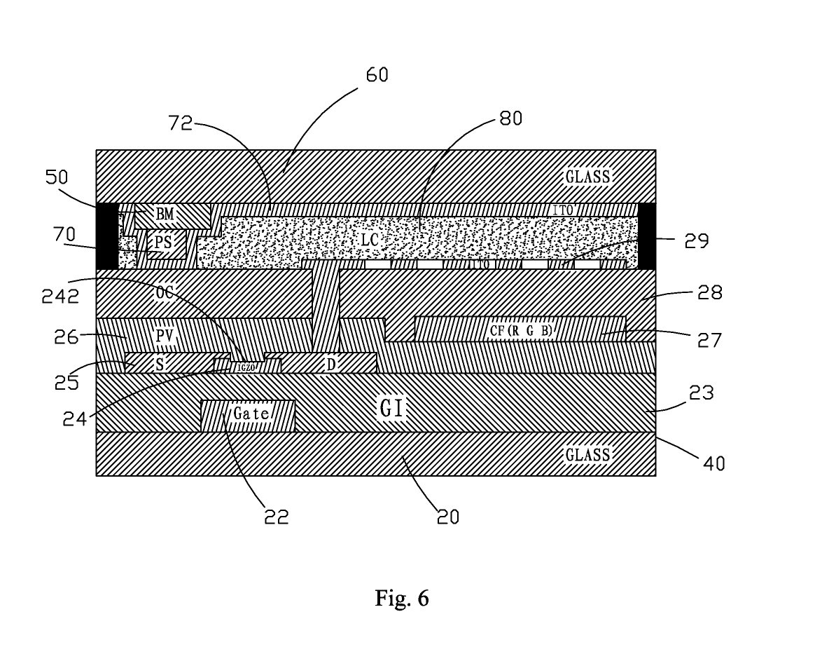

Referring to FIG. 6, as well as FIGS. 4 and 5, the present invention further provides a liquid crystal display panel, which comprises: an array substrate 40, a color filter substrate 60 laminated to the array substrate 40, and a liquid crystal layer 80 arranged between the array substrate 40 and the color filter substrate 60. The array substrate 40 comprises: a glass substrate 20, a gate terminal 22 formed on the glass substrate 20, a gate insulation layer 23 formed on the gate terminal 22 and the glass substrate 20, an oxide semiconductor layer 24 formed on the gate insulation layer 23, source/drain terminals 25 formed on the oxide semiconductor layer 24 and the gate insulation layer 23, a protective layer 26 formed on the oxide semiconductor layer 24, the source/drain terminals 25, and the gate insulation layer 23, a color filter 27 formed on the protective layer 26, a planarization layer 28 formed on the color filter 27 and the protective layer 26, and a pixel electrode 29 formed on the planarization layer 28. The pixel electrode 29 is electrically connected to the source/drain terminals 25 and the pixel electrode 29 comprises an arrangement of lines that forms a radiating structure surrounding a center defined by a cross-shaped structure so as to effectively increase the aperture ratio and enhance the displaying performance.

The gate terminal 22, the gate insulation layer 23, the oxide semiconductor layer 24, and the source/drain terminals 25 collectively constitute a thin-film transistor, which drives liquid crystal molecules contained in the liquid crystal layer 80 to rotate so as to realize selection of light and thus achieve displaying. The color filter 27 functions to realize color displaying.

Further, the oxide semiconductor layer 24 comprises a recess 242 formed thereon to be located between the source/drain terminals 25. The protective layer 26 is formed on the source/drain terminals 25, the gate insulation layer 23, and the recess 242. A specific manufacture operation is that after the oxide semiconductor layer 24 is formed on the gate insulation layer 23, a second metal layer is formed on the oxide semiconductor layer 24 and the gate insulation layer 23 and the second metal layer is subjected to etching to form the source/drain terminals 25. Under this condition, the portion of the oxide semiconductor layer 24 between the source/drain terminals 25 is exposed. The surface of the exposed portion is damaged due to being bombarded by the second metal layer and this leads to poor property of the thin-film transistor. By subjecting the exposed portion of the oxide semiconductor layer 24 to etching again to etch off the damaged portion, it can then ensure the property of the thin-film transistor.

In the instant embodiment, the oxide semiconductor layer 24 is an indium gallium zinc oxide layer. The pixel electrode 29 is formed of nano indium tin oxide.

It is noted that the liquid crystal display panel of the present invention further comprises a black matrix 50 and a spacer 70 arranged between the array substrate 40 and the color filter substrate 60. The black matrix 50 and the spacer 70 are formed on the color filter substrate 60 or the array substrate 40. In the instant embodiment, the black matrix 50 and the spacer 70 are formed on the color filter substrate 60 and are located under a common electrode 72 that is formed on the color filter substrate 60.

In summary, the present invention provides an array substrate and a liquid crystal display panel using the array substrate, in which a color filter is arranged on the array substrate and a pixel electrode is provided in an arrangement of lines that forms a radiating structure surrounding a center defined by a cross-shaped structure so as to effectively increase the aperture ratio and enhance the displaying performance. Further, a recess is formed in the oxide semiconductor layer between the source/drain terminals to remove the damaged portion of the surface of the oxide semiconductor layer resulting from the forming of the source/drain terminals so as to effectively improve electrical property and enhance the quality of the liquid crystal display panel.

Based on the description given above, those having ordinary skills of the art may easily contemplate various changes and modifications of the technical solution and technical ideas of the present invention and all these changes and modifications are considered within the protection scope of right for the present invention.

What is claimed is:

1. An array substrate, comprising: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer, the pixel electrode being electrically connected to the source/drain terminals, the pixel electrode comprising an arrangement of lines that forms a radiating structure surrounding a center defined by a cross-shaped structure.

2. The array substrate as claimed in claim 1, wherein the oxide semiconductor layer comprises a recess formed thereon to be located between the source/drain terminals and the protective layer is formed on the source/drain terminals, the gate insulation layer, and the recess.

3. The array substrate as claimed in claim 1, wherein the oxide semiconductor layer comprises an indium gallium zinc oxide layer.

4. The array substrate as claimed in claim 1, wherein the pixel electrode is formed of nano indium tin oxide.

5. A liquid crystal display panel, comprising: an array substrate, a color filter substrate laminated to the array substrate, and a liquid crystal layer arranged between the array substrate and the color filter substrate, the array substrate comprising: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer, the pixel electrode being electrically connected to the source/drain terminals, the pixel electrode comprising an arrangement of lines that forms a radiating structure surrounding a center defined by a cross-shaped structure.

6. The liquid crystal display panel as claimed in claim 5, wherein the oxide semiconductor layer comprises a recess formed thereon to be located between the source/drain terminals and the protective layer is formed on the source/drain terminals, the gate insulation layer, and the recess.

7. The liquid crystal display panel as claimed in claim 5, wherein the oxide semiconductor layer comprises an indium gallium zinc oxide layer and the pixel electrode is formed of nano indium tin oxide.

8. The liquid crystal display panel as claimed in claim 5 further comprising a black matrix and a spacer arranged between the array substrate and the color filter substrate.

9. The liquid crystal display panel as claimed in claim 8, wherein the black matrix and the spacer are formed on the color filter substrate.

10. The liquid crystal display panel as claimed in claim 8, wherein the black matrix and the spacer are formed on the array substrate.

11. A liquid crystal display panel, comprising: an array substrate, a color filter substrate laminated to the array substrate, and a liquid crystal layer arranged between the array substrate and the color filter substrate, the array substrate comprising: a glass substrate, a gate terminal formed on the glass substrate, a gate insulation layer formed on the gate terminal and the glass substrate, an oxide semiconductor layer formed on the gate insulation layer, source/drain terminals formed on the oxide semiconductor layer and the gate insulation layer, a protective layer formed on the oxide semiconductor layer, the source/drain terminals, and the gate insulation layer, a color filter formed on the protective layer, a planarization layer formed on the color filter and the protective layer, and a pixel electrode formed on the planarization layer, the pixel electrode being electrically connected to the source/drain terminals, the pixel electrode comprising an arrangement of lines that forms a radiating structure surrounding a center defined by a cross-shaped structure;
wherein the oxide semiconductor layer comprises a recess formed thereon to be located between the source/drain terminals and the protective layer is formed on the source/drain terminals, the gate insulation layer, and the recess.

12. The liquid crystal display panel as claimed in claim 11, wherein the oxide semiconductor layer comprises an indium gallium zinc oxide layer and the pixel electrode is formed of nano indium tin oxide.

13. The liquid crystal display panel as claimed in claim 11 further comprising a black matrix and a spacer arranged between the array substrate and the color filter substrate.

14. The liquid crystal display panel as claimed in claim 13, wherein the black matrix and the spacer are formed on the color filter substrate.

15. The liquid crystal display panel as claimed in claim 13, wherein the black matrix and the spacer are formed on the array substrate.
